(19) United States
(12) Patent Application Publication
(10) Pub. No.: US 2010/0003110 A1
(43) Pub. Date: Jan. 7, 2010

(54) SUCTION HOLDING APPARATUS AND SUCTION HOLDING METHOD

(76) Inventor: Noriyuki Yokota, Kanagawa (JP)

Correspondence Address: SNELL & WILMER LLP (OC), 600 ANTON BOULEVARD, SUITE 1400, COSTA MESA, CA, 92626, US

(21) Appl. No.: 12/304,724

(22) PCT Filed: Jun. 12, 2007
(86) PCT No.: PCT/JP2007/000621

§ 371 Date: Apr. 29, 2009

(30) Foreign Application Priority Data
Jun. 13, 2006 (JP) 2006-163938

(51) Int. Cl. H01L 21/683; B65G 49/07

(52) U.S. Cl. 414/217.1

(57) ABSTRACT

The invention provides a suction holding apparatus and a suction holding method that allow suction-holding a substrate reliably irrespective of substrate type, with a simple and inexpensive structure. The suction holding apparatus comprises a suction plate (2) having a suction surface (21); a lifting mechanism for changing the relative position of a glass substrate (P1) and the suction plate (2); a. temperature changing section (5) for changing the temperature of the suction surface (21); and a control device (100) for controlling the temperature changing section (5) so as to cause dew condensation on the suction surface (21) when the glass substrate (P1) is suctioned onto the suction surface (21). The suction surface (21) is cooled to a temperature at or below the dew point temperature, whereupon the glass substrate (P1) is suctioned by way of condensed water, and is bonded to a counter substrate (P2).

### TECHNICAL FIELD

The present invention relates to a suction holding apparatus and a suction holding method for suction-holding a substrate, in order to bond, for instance, flat plate-like substrates such as glass substrates.

### BACKGROUND

Liquid crystal panels, organic EL panels and the like are manufactured by, for instance, bonding together glass substrates. Glass substrates, therefore, must be held in the bonding device. Ordinary methods for holding a substrate include, for instance, vacuum suction, as well as holding by way of mechanical chucks, electrostatic chucks and the like.

With a view to, for instance, eliminating air bubbles, vacuum bonding is used in the manufacturing process of liquid crystal panels and the like. The holding apparatus need to hold a substrate from above it in the vacuum area. To this end, Mechanical or electrostatic chucks are often used as well, since the holding force of vacuum suction cannot be maintained.

Patent document 1: Japanese Patent Application Laid-open No. 2003-330031

Patent document 2: Japanese Patent Application Laid-open No. 2002-154647

However, holding of a substrate by way of a mechanical chuck requires a gripping part. As a result, bonding to another substrate of identical size is hampered by the gripped portion, so that the substrate held by the chuck cannot be brought into close contact, in that state, against the other substrate. Meanwhile, the suction force of electrostatic chucks varies greatly depending, for instance, on whether or not a conductive film is formed on the substrate. A further concern is that application of high voltages, of several kV or higher, may damage circuits on the substrate.

To address the above shortcomings, Patent document 1 discloses a technique that involves supplying water onto a substrate, lowering a holding plate to bring the latter into contact with the substrate, and suctioning the substrate against the holding plate, by way of the surface tension of the water interposed between the holding plate and the substrate. Patent document 2 discloses a technique of supplying silicone oil via a plurality of small holes formed on a suction plate that is brought into contact with a substrate, so that the substrate is suctioned on account of the surface tension of the silicone oil interposed between the suction plate and the substrate.

In the above techniques, however, a liquid must be actively supplied onto the substrate. The liquid, therefore, must be prepared beforehand, and there must be provided a device for supplying the liquid, all of which result in a complex and costly apparatus structure that is awkward to control. Moreover, such techniques are inappropriate for products in which large amounts of residual liquid are to be avoided.

### DISCLOSURE OF THE INVENTION

An object of the present invention, which is proposed with a view to solving the above problems of conventional art, is to provide a suction holding apparatus and a suction holding method that allow suction-holding a substrate reliably irrespective of substrate type, with a simple and inexpensive structure.

To achieve the above goal, the present invention is a suction holding apparatus for suction-holding a substrate, comprising: suction means having a suction surface; driving means for changing the relative position of the substrate and the suction means; temperature changing means for changing the temperature of the suction surface; and control means for controlling the temperature changing means so as to cause dew condensation on the suction surface when the substrate is suctioned onto the suction surface.

An embodiment of the method of the present invention is a suction holding method for suction-holding a substrate, comprising the steps of causing dew condensation on a suction surface of suction means, by changing the temperature of the suction surface; and pressure-bonding the substrate against the suction surface.

In such an invention, moisture in the atmosphere is condensed on the suction surface of the suction means by changing the temperature of the suction surface. When the substrate is affixed to the suction surface, water spreads very thinly therebetween, and the substrate becomes suctioned strongly onto the suction surface on account of surface tension. The substrate can thus be suctioned onto the suction means by way of a simple temperature control.

In another embodiment, the control means is provided with dew point detection means for detecting a dew point.

In such an embodiment, there is detected the dew point in a changeable atmosphere, so that a desired dew condensation can be achieved at all times by controlling the apparatus on the basis of the detected dew point.

In another embodiment, the temperature changing means has a Peltier element.

Such an embodiment resorts to a Peltier element, having no movable parts or the like, for changing the temperature. Both the structure and the control of the apparatus can be made easier as a result.

In another embodiment, the suction means is provided in a vacuum chamber in which vacuum can be formed, the vacuum chamber being connected to a vacuum source.

In such an embodiment, condensed water ensures reliable suction while averting the influence of air, for instance, during bonding, thanks to the vacuum that is formed.

As explained above, therefore, the present invention succeeds in providing a suction holding apparatus and a suction holding method that allow suction-holding a substrate reliably irrespective of substrate type, with a simple and inexpensive structure.

### BRIEF DESCRIPTION OF THE DRAWINGS

FIG. 1 is a set of vertical cross-sectional diagrams illustrating an embodiment of the suction holding apparatus of the present invention during substrate carry-in (A), during suction holding (B), during evacuation (C), and during bonding (D);

FIG. 2 is a block diagram illustrating the configuration of a control device in the embodiment of FIG. 1; and

FIG. 3 is a flowchart illustrating a suction-holding and bonding sequence in the embodiment of FIG. 1.

### BEST MODE FOR CARRYING OUT THE INVENTION

Embodiments of the present invention (referred to hereinafter as embodiments) are explained in detail below with reference to accompanying drawings.

### Constitution of the Embodiments

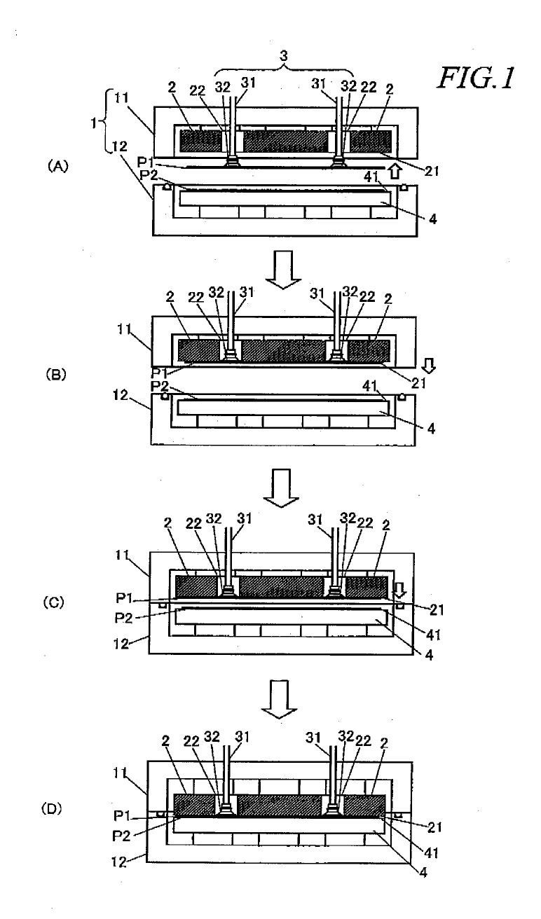

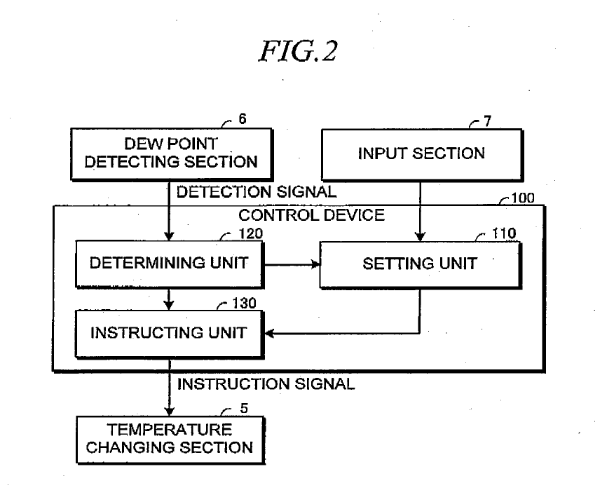

The constitution of a suction holding apparatus of the present embodiment (hereinafter, the present apparatus) will be explained first with reference to FIGS. 1 and 2. The present apparatus makes up part of a bonding apparatus in which, for instance, a glass substrate for liquid crystal panels is bonded to a counter substrate, of identical size, that is coated with a sealing agent and a liquid crystal. In order to hold the glass substrate in vacuum there is used a suction plate that exploits the surface tension of a liquid. The substrate-conveying equipment that is disposed upstream of the present apparatus, as well as mechanisms for delivering the substrate, and dispensers or the like for coating the substrate with the sealing agent and the liquid crystal, rely all on conventionally known technologies, and thus an explanation thereof will be omitted.

Specifically, the present apparatus comprises, for instance, a vacuum chamber 1, a suction plate 2, a handling device 3, a lower plate 4, a temperature changing section 5, a control device 100, a dew point detecting section 6 and an input section 7, as illustrated in FIG. 1. The vacuum chamber 1 comprises an upper container 11 and a lower container 12. A vacuum chamber forms inside the vacuum chamber 1 when the upper container 11, which is moved up and down by a lifting mechanism, not shown, comes into contact with the lower container 12. This vacuum chamber, which is connected to a vacuum source, not shown, is constructed so as to be capable of being depressurized.

The suction plate (suction means) 2 is a plate having, on the underside thereof, a suction surface 21 for suctioning a glass substrate P1. As the suction surface 21 there may be used, for instance, glass, a mirror-surface finished material or a polyimide. Preferably, the surface roughness Rmax is no greater than 0.1 μm. The present invention, however, is not limited to such materials or surface roughness.

The suction plate 2 is provided in such a manner that it can be raised and lowered within the vacuum chamber 1 by way of the lifting mechanism (driving means) not shown. The suction plate 2 has formed therein through-holes 22 through which there move below-described suction arms 31. A temperature changing section 5 (see FIG. 2), for cooling and heating the suction surface 21, is provided inside the suction plate 2. The temperature changing section 5 comprises a Peltier element for cooling or heating, when being energized, in response to an instruction by the control device 100. The temperature changing section 5 need only be capable of changing the temperature of the suction surface 21, and hence the temperature changing section 5 is not limited to a Peltier element, while the arrangement position and number of temperature changing sections 5, and whether or not the temperature changing section 5 is to be integrated as a single section with the suction plate 2, among other features, are matter of free design.

The handling device 3 comprises a plurality of suction arms 31 and vacuum pads 32. The suction arms 31 are provided so as to be capable of being raised and lowered by the lifting mechanism not shown. The vacuum pads 32 are provided at respective tips of the suction arms 31, and are connected to the vacuum source not shown. As a result, the glass substrate P1 is sucked onto the vacuum pads 32 when the suction arms 31 are lowered and pressure is reduced by the vacuum source. The lower plate 4 is provided in the lower container 12. The top face of the lower plate 4 constitutes a base section 41 on which there is placed a counter substrate P2 of identical size to that of the glass substrate P1.

The control device 100 is means for controlling, among others, the operation of the above-described vacuum source and lifting mechanism, as well as the temperature of the temperature changing section 5. As illustrated in FIG. 2, the control device 100 is connected to the dew point detecting section 6 for detecting the dew point of the atmosphere, and the input section 7 for inputting information, such as settings. The dew point detecting section 6 may be disposed anywhere, provided that it can detect the dew point around the substrate immediately before suction The number of dew point detecting sections 6 is not limited.

In the control device 100 there are set a determining unit 120 for dew point determination on the basis of the values detected by the dew point detecting section 6; a setting unit 110 for, by way of the input section 7, setting a predetermined temperature such that the temperature of the suction surface 21 is not higher than the dew point; and an instructing unit 130 four outputting an instruction signal to the temperature changing section 5 on the basis of determination by the determining unit 120 and the settings of the setting unit 110. Although not limited thereto, the set predetermined temperature can be set, for instance, to a temperature 10 to 20° C. below the dew point.

Such a control device 100 can be realized in, for instance, a dedicated electronic circuit or in a computer running a predetermined program. Therefore, a computer program for controlling the operation of the present device in accordance with the explanation below, and the recording medium in which the computer program is stored, constitute both an aspect of the present invention.

### Operation of the Embodiment

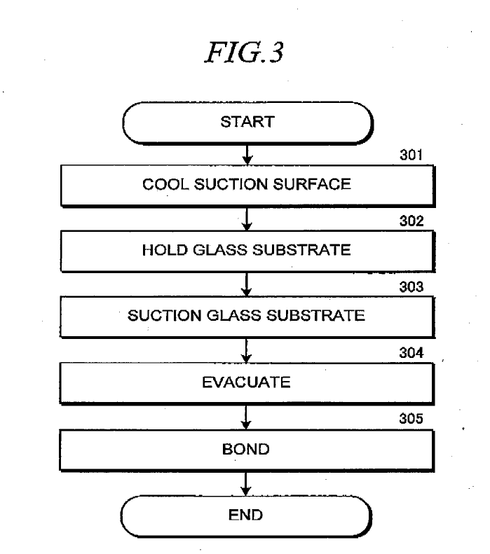

The suction and bonding procedure of a glass substrate in the present embodiment will be explained with reference to FIGS. 1 and 2, as well as the flowchart of FIG. 3. Firstly, as illustrated in FIG. 1(A), the upper container 11 of the vacuum chamber 1 is raised away from the lower container 12. With the vacuum chamber 1 thus open to the atmosphere, the Peltier element of the temperature changing section 5 is energized, to cool the suction surface 21 (step 301).

The temperature changing section 5 sets the suction surface 21 to be cooled to a given temperature that is lower than the dew point temperature detected by the dew point detecting section 6, as described above, so that water vapor in the atmosphere condenses as a result on the suction surface 21. The glass substrate P1 is then conveyed into the vacuum chamber 1 that is open to the atmosphere. The top face of the glass substrate P1 is held, through vacuum suction, by the vacuum pads 32 of the suction arms 31 (step 302). The counter substrate P2, coated beforehand, by way of a dispenser, with a sealing agent and a liquid crystal, is placed meanwhile on the base section 41 of the lower plate 4.

Next, as illustrated in FIG. 1(B), the glass substrate P1, vacuum-suctioned against the vacuum pads 32, is lifted up through raising of the suction arms 31, whereby the top face of the glass substrate P1 is brought into close contact with the suction surface 21 of the suction plate 2 (step 303). A suction force is generated thereupon on account of the surface tension of the water that condenses and adheres to part of the adhesion surface between the glass substrate P1 and the suction surface 21. Over time, the suction surface area extends across virtually the entire surface.

As these members, having an extremely small surface roughness, are brought together into close contact, sandwiching a small amount of liquid therebetween, the liquid spreads very thinly between the members, whereupon the surface tension of the liquid gives rises to a strong suction force. The amount of liquid may be so small as to be undetectable to the naked eye.

As illustrated in FIG. 1(C), the upper container 11 is lowered and brought into close contact with the lower container 12, to seal the interior of the vacuum chamber 1, which is subsequently evacuated by the vacuum source (step 304). Since the glass substrate P1 is suctioned against the suction surface 21 of the suction plate 2 on account of the surface tension of water, the suction force is maintained even when the space around the glass substrate P1 is evacuated.

In this state, the suction plate 2 and the suction arms 31 are lowered to press and bond thereby the glass substrate P1 against the counter substrate P2, as illustrated in FIG. 1(D) (step 305). The suction force is thus maintained by the small amount of water, even in vacuum, so that the glass substrate P1 can be pressed against the counter substrate P2, of identical size, by suction-holding only the top face of the glass substrate P1.

### Effect of the Embodiment

The present embodiment, thus, requires no gripping part such as a mechanical chuck, and thus the counter substrate P2 and the glass substrate P1 of identical size can be bonded together. Also, no voltage needs to he applied to the glass substrate P1, and hence bonding can be carried out safely and reliably, regardless of substrate type and of the presence or absence of conductive films, circuits and the like.

The apparatus uses simply water condensed out of the atmosphere, by lowering the temperature, without any liquid being supplied to the suction surface 21. As a result, management of the apparatus is straightforward, while the cost of the apparatus can be reduced thanks to its simple structure. In particular, the water used for suction can be controlled by temperature management alone, while the cooling means used is a Peltier element. This makes for a simple and inexpensive system, little prone to malfunction, and easy to service.

Also, the apparatus utilizes small amounts water condensed on the suction surface 21. Homogeneous suction can thus be achieved naturally as a result even in case of large substrates. The apparatus can also be employed for products in which a substantial amount of residual liquid is best avoided.

### Other Embodiments

The present invention is not limited to the above-described embodiment. The cooling temperature need only be such a temperature (for instance, a temperature not higher than the dew point) as to allow condensation on the suction surface. Accordingly, the cooling temperature is not limited to the temperature exemplified in the above embodiment. Detection of the dew point is not mandatory, and there may be set, as a default, a given temperature that should foreseeably make condensation possible.

When the atmosphere dew point is controlled to be substantially constant, for instance in a factory, a desired level of condensation can be confidently achieved when the apparatus is cooled down to a given temperature, even without detecting the dew point. Condensing water can also be controlled in concert with temperature control, by supplying a gas of desired humidity.

Bonding may be carried out in the atmosphere, or in an inert gas such as N₂. Various techniques may be employed for releasing the suctioned substrate. The substrate may be released, for instance, by air blowing. The substrate may also be rendered easier to release through heating by the temperature changing means.

The substrates for which the present invention can be used can be freely selected in terms of size, shape, material, as well as presence or absence of conductive films or circuits. The pair of substrates to be bonded need not necessarily be of identical size. The invention is not limited to known standards such as those of liquid crystal panels, plasma display panels and organic EL panels, but can also be suitably employed for any standards that come into use in the future. The present invention, moreover, can be used not only for the above-described panels, but also for any kind of substrate that needs to be suction-held during a manufacturing operation.

1. A suction holding apparatus for suction-holding a substrate, comprising:
suction means having a suction surface;
driving means for changing the relative position of said substrate and said suction means;
temperature changing means for changing the temperature of said suction surface; and
control means for controlling said temperature changing means so as to cause dew condensation on said suction surface.

2. The suction holding apparatus according to claim 1, wherein said control means is provided with dew point detection means for detecting a dew point.

3. The suction holding apparatus according to claim 1, wherein said temperature changing means has a Peltier element.

4. The suction holding apparatus according to claim 1, wherein said suction means is provided in a vacuum chamber in which vacuum can be formed, and said vacuum chamber is connected to a vacuum source.

5. A suction holding method for suction-holding a substrate, comprising the steps of:
causing dew condensation on a suction surface of suction means, by changing the temperature of the suction surface; and
pressure-bonding said substrate against said suction surface.

6. The suction holding apparatus according to claim 2, wherein said suction means is provided in a vacuum chamber in which vacuum can be formed, and said vacuum chamber is connected to a vacuum source.

7. The suction holding apparatus according to claim 3, wherein said suction means is provided in a vacuum chamber in which vacuum can be formed, and said vacuum chamber is connected to a vacuum source.
